(19) United States
(12) Patent Application Publication
(10) Pub. No.: US 2011/0097553 A1
(43) Pub. Date: Apr. 28, 2011

(54) TRENCH SUBSTRATE AND METHOD OF FABRICATING THE SAME

(76) Inventors: Jong Kuk Hong, Gyunggi-do (KR); Soon Jin Cho, Chungcheongbuk-do (KR); Sun Uk Hwang, Seoul (KR)

(21) Appl. No.: 12/631,624

(22) Filed: Dec. 4, 2009

(30) Foreign Application Priority Data
Oct. 23, 2009 (KR) 10-2009-0100997

(51) Int. Cl. H05K 1/03; B32B 3/30; H05K 3/00

(52) U.S. Cl. 428/173; 427/97.4

(57) ABSTRACT

Disclosed is a trench substrate, which includes a first insulating layer having trenches formed therein, a second insulating layer disposed on a lower surface of the first insulating layer and having laser processability inferior to that of the first insulating layer, and a negative pattern formed in the trenches, and in which the second insulating layer having laser processability inferior to that of the first insulating layer functions as a stopper, so that the trenches having the same shape are formed in the first insulating layer, thus enabling the formation of a fine and uniform circuit pattern. A method of fabricating the trench substrate is also provided.

### CROSS REFERENCE TO RELATED APPLICATION

This application claims the benefit of Korean Patent Application No. 10-2009-0100997, filed Oct. 23, 2009, entitled “A Trench Substrate and A Fabricating Method The Same”, which is hereby incorporated by reference in its entirety into this application.

### BACKGROUND OF THE INVENTION

1. Technical Field

The present invention relates to a trench substrate and a method of fabricating the same.

2. Description of the Related Art

Generally, a printed circuit board (PCB) is fabricated by forming a copper wiring pattern on either or both surfaces of a board made of any type of thermosetting synthetic resin, disposing and fixing IC or electronic components on the board, and electrically connecting the IC or electronic components, and coating the board with an insulator.

Alongside the recent advancement of the electronics industry is a drastically increasing demand for electronic components with increased functionality. A PCB which mounts such electronic components is also required to have a high-density wiring pattern. Thus, in the course of fabrication of a PCB, a process for forming an electrical wiring circuit pattern, in particular, a process for forming a fine circuit pattern, is under thorough study.

The process for forming a fine circuit pattern includes a semi-additive process including performing electroless copper plating and copper electroplating on an insulating layer thus forming a fine circuit pattern. However, because the circuit pattern resulting from a conventional semi-additive process is provided in the form of a positive pattern on the insulating layer, it may be undesirably separated from the insulating layer. As the circuit pattern becomes finer, the contact area between the insulating layer and the circuit pattern is reduced, thus weakening the force of adhesion therebetween, undesirably causing problems of the circuit pattern easily separating. Furthermore, there may occur problems of the circuit pattern undergoing an undercut phenomenon in the course of etching.

Recently, in order to overcome such problems, an LPP (Laser Patterning Process) is receiving attention, which includes forming trenches on the insulating layer using a laser, and performing plating, polishing and etching, thus forming a circuit pattern. FIGS. 1 and 2 are cross-sectional views sequentially showing a process of fabricating a trench substrate according to a conventional technique.

As shown in FIGS. 1 and 2, the trench substrate 10 according to the conventional technique is fabricated by processing trenches 16 on an insulating layer 12 using a laser 14 (FIG. 1), and plating the trenches 16, thus forming a negative pattern 18 (FIG. 2).

However, in the case where the trenches 16 are processed on the insulating layer 12 made of the same material as in the conventional technique, it is not easy to control the depth d of the trenches 16, undesirably forming trenches 16 having different depths d. In the case where the trenches 16 have different depths d, the width w thereof may vary, so that the trenches 16 may have a non-uniform shape and thus the negative pattern 18 formed in the trenches 16 may inevitably have a non-uniform shape. Hence, it is difficult to form a fine and uniform circuit pattern.

### SUMMARY OF THE INVENTION

Accordingly, the present invention has been made keeping in mind the problems encountered in the related art and the present invention is intended to provide a trench substrate in which trenches are processed to have the same shape thus achieving a fine and uniform circuit pattern, and also to provide a method of fabricating the same.

An aspect of the present invention provides a trench substrate, including a first insulating layer having trenches formed therein, a second insulating layer disposed on a lower surface of the first insulating layer and having laser processability inferior to that of the first insulating layer, and a negative pattern formed in the trenches.

In this aspect, the second insulating layer may be formed of a material different from that of the first insulating layer.

In this aspect, the second insulating layer may be formed of a material having laser absorptivity lower than that of the first insulating layer.

Furthermore, the first insulating layer may be formed of a material having a dark color, and the second insulating layer may be formed of a material having a bright color.

In this aspect, the second insulating layer may be formed of a material which is the same as or different from that of the first insulating layer, and may include therein either or both of glass fiber and a filler.

Furthermore, the filler may include one or more selected from the group consisting of calcium, aluminum, magnesium, silicon, boron, and barium.

In this aspect, glass fiber may be formed between the first insulating layer and the second insulating layer.

Another aspect of the present invention provides a trench substrate, including an insulating layer including glass fiber therein and trenches formed at one side of the glass fiber, and a negative pattern formed in the trenches.

In this aspect, an insulating layer located at the other side of the glass fiber may include therein either or both of glass fiber and a filler.

Furthermore, the filler may include one or more selected from the group consisting of calcium, aluminum, magnesium, silicon, boron, and barium.

A further aspect of the present invention provides a method of fabricating the trench substrate, including providing a first insulating layer and forming a second insulating layer having laser processability inferior to that of the first insulating layer on a lower surface of the first insulating layer, forming trenches in the first insulating layer using a laser, and plating the trenches, thus forming a negative pattern.

In this aspect, the second insulating layer may be formed of a material different from that of the first insulating layer.

In this aspect, the second insulating layer may be formed of a material which is the same as or different from that of the first insulating layer, and includes therein either or both of glass fiber and a filler.

Furthermore, the filler may include one or more selected from the group consisting of calcium, aluminum, magnesium, silicon, boron, and barium.

In this aspect, glass fiber may be formed between the first insulating layer and the second insulating layer.

Still a further aspect of the present invention provides a method of fabricating the trench substrate, including providing an insulating layer including glass fiber therein and forming trenches at one side of the glass fiber, and plating the trenches, thus forming a negative pattern.

In this aspect, an insulating layer located at the other side of the glass fiber may include therein either or both of glass fiber and a filler.

Furthermore, the filler may include one or more selected from the group consisting of calcium, aluminum, magnesium, silicon, boron, and barium.

### BRIEF DESCRIPTION OF THE DRAWINGS

The features and advantages of the present invention will be more clearly understood from the following detailed description taken in conjunction with the accompanying drawings, in which:

FIGS. 1 and 2 are cross-sectional views sequentially showing a process of fabricating a trench substrate according to a conventional technique;

FIG. 3 is a cross-sectional view showing a trench substrate according to a first embodiment of the present invention;

FIG. 4 is a cross-sectional view showing a trench substrate according to a second embodiment of the present invention;

FIG. 5 is a cross-sectional view showing a trench substrate according to a third embodiment of the present invention;

FIG. 6 is a cross-sectional view showing a trench substrate according to a fourth embodiment of the present invention;

FIGS. 7 to 9 are cross-sectional views sequentially showing a process of fabricating the trench substrate according to the first embodiment of the present invention;

FIGS. 10 to 12 are cross-sectional views sequentially showing a process of fabricating the trench substrate according to the second embodiment of the present invention;

FIGS. 13 to 15 are cross-sectional views sequentially showing a process of fabricating the trench substrate according to the third embodiment of the present invention; and

FIGS. 16 to 18 are cross-sectional views sequentially showing a process of fabricating the trench substrate according to the fourth embodiment of the present invention.

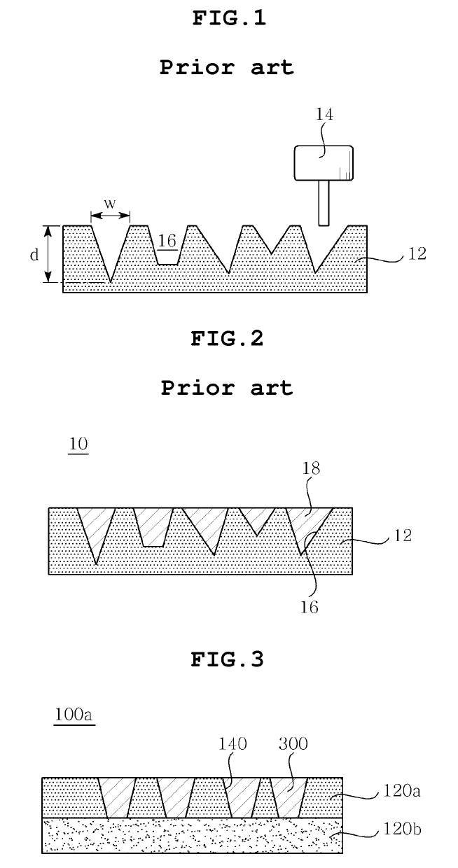

### DESCRIPTION OF SPECIFIC EMBODIMENTS

Hereinafter, embodiments of the present invention will be described in detail while referring to the accompanying drawings. Throughout the drawings, the same reference numerals are used to refer to the same or similar elements. Moreover, descriptions of known techniques, even if they are pertinent to the present invention, are regarded as unnecessary and may be omitted in so far as they would make the characteristics of the invention unclear and render the description unclear.

Furthermore, the terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept implied by the term to best describe the method he or she knows for carrying out the invention.

### Trench Substrate

### 1^{st} Embodiment

FIG. 3 is a cross-sectional view showing a trench substrate according to a first embodiment of the present invention. With reference to this drawing, the trench substrate 100a according to the present embodiment is described below.

As shown in FIG. 3, the trench substrate 100a according to the present embodiment is configured such that a first insulating layer 120a having trenches 140 formed therein is prepared, a second insulating layer 120b having laser processability inferior to that of the first insulating layer 120a is formed on the lower surface of the first insulating layer 120a, and a negative pattern 300 is formed in the trenches 140.

The second insulating layer 120b may be formed using a material having laser processability inferior to that of the first insulating layer 120a, different from the material of the first insulating layer 120a. Alternatively, the second insulating layer 120b may be formed using a material having lower laser absorptivity, namely, a material having higher laser reflectivity, compared to the first insulating layer 120a. For example, the first insulating layer 120a may be formed using a material having high laser absorptivity and a dark color, and the second insulating layer 120b may be formed using a material having low laser absorptivity and a bright color, whereby the laser processability may vary depending on the laser absorptivity (or reflectivity).

As such, the negative pattern 300 has the same thickness and the same width because the trenches 140 are processed only in the first insulating layer 120a and thus have the same depth.

### Trench Substrate

### 2^{nd} Embodiment

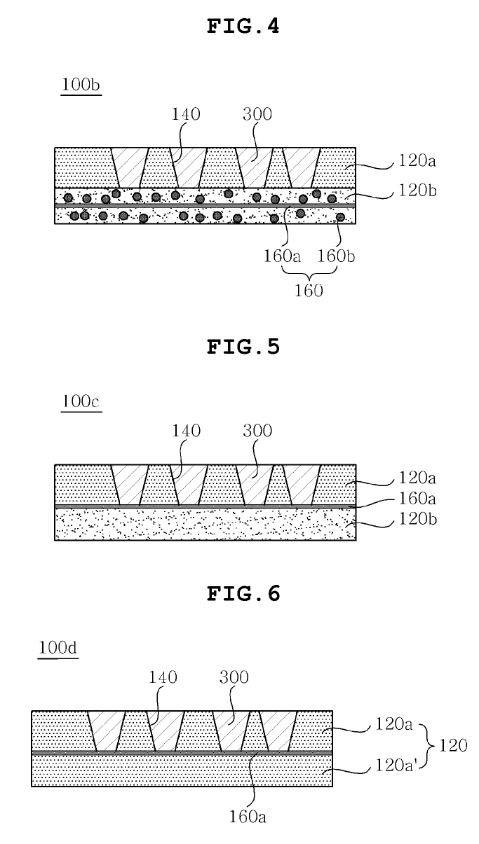

FIG. 4 is a cross-sectional view showing a trench substrate according to a second embodiment of the present invention. With reference to this drawing, the trench substrate 100b according to the present embodiment is described below.

As shown in FIG. 4, the trench substrate 100b according to the present embodiment is configured such that a first insulating layer 120a having trenches 140 in which a negative pattern 300 is formed is prepared, and a second insulating layer 120b is formed on the lower surface of the first insulating layer 120a using a material which is the same as or different from the material of the first insulating layer 120a, in which the second insulating layer 120b includes a reinforcement member 160 therein so as to have laser processability inferior to that of the first insulating layer 120a.

The reinforcement member 160 may include glass fiber 160a and/or a filler 160b, and is incorporated in the second insulating layer 120b to thus reinforce electrical insulating properties, mechanical strength, rigidity and dimensional stability of the second insulating layer 120b, thereby reducing laser processability of the second insulating layer 120b. As such, even when the second insulating layer 120b is formed using the same material as in the first insulating layer 120a, it includes the reinforcement member 160 therein and thus has laser processability inferior to that of the first insulating layer 120a. For sake of illustration, FIG. 4 shows the second insulating layer 120b which is formed of a material different from the material of the first insulating layer 120a and includes both the glass fiber 160a and the filler 160b therein.

The glass fiber 160a has a structure in which short fiber bundles having a diameter of 5˜9 μm are woven, and the filler 160b may include one or more inorganic fillers selected from among calcium (Ca), aluminum (Al), magnesium (Mg), silicon (Si), boron (B), and barium (Ba).

### Trench Substrate

### 3^{rd} Embodiment

FIG. 5 is a cross-sectional view showing a trench substrate according to a third embodiment of the present invention. With reference to this drawing, the trench substrate 100c according to the present embodiment is described below.

As shown in FIG. 5, the trench substrate 100c according to the present embodiment is configured such that glass fiber 160a is disposed between the first insulating layer 120a and the second insulating layer 120b of the trench substrate 100a according to the first embodiment.

As such, the glass fiber 160a, which is disposed between the first insulating layer 120a and the second insulating layer 120b, functions as a stopper when trenches 140 are processed in the first insulating layer 120a, so that the trenches 140 have the same depth.

Although not shown, the trench substrate 100c according to the present embodiment may be configured such that the second insulating layer 120b includes the reinforcement member 160 therein as in the second embodiment.

### Trench Substrate

### 4^{th} Embodiment

FIG. 6 is a cross-sectional view showing a trench substrate according to a fourth embodiment of the present invention. With reference to this drawing, the trench substrate 100d according to the present embodiment is described below.

As shown in FIG. 6, the trench substrate 100d according to the present embodiment is configured such that an insulating layer 120 having glass fiber 160a incorporated therein is prepared, trenches 140 are formed in an insulating layer 120a located at one side of the glass fiber of the insulating layer 120, and a negative pattern 300 is formed in the trenches 140.

As such, the glass fiber 160a may be incorporated in the insulating layer 120, in particular, in the center of the insulating layer 120 in a longitudinal direction. Thus, when trenches are processed in the insulating layer 120a located at one side of the glass fiber of the insulating layer 120, the glass fiber functions as a stopper, so that the trenches 140 have the same depth.

Although not shown, the trench substrate 100d according to the present embodiment may be configured such that an insulating layer 120a′ located at the other side of the glass fiber of the insulating layer 120 includes a reinforcement member 160.

### Fabrication of Trench Substrate

### 1^{st} Embodiment

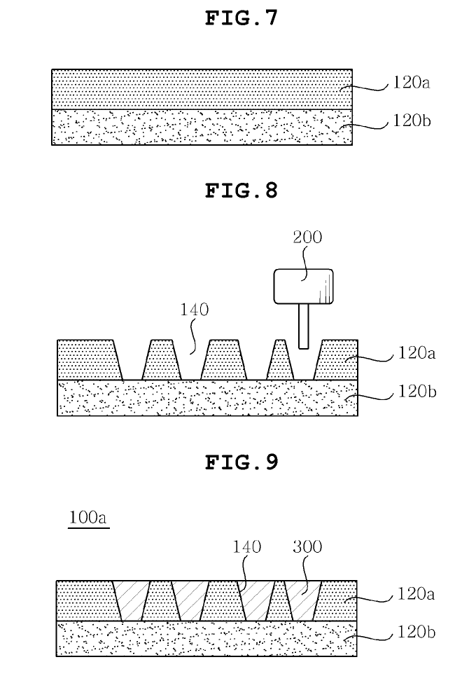

FIGS. 7 to 9 are cross-sectional views sequentially showing a process of fabricating the trench substrate according to the first embodiment of the present invention. With reference to these drawings, the method of fabricating the trench substrate according to the present embodiment is described below.

As shown in FIG. 7, a first insulating layer 120a is prepared, and a second insulating layer 120b having laser processability inferior to that of the first insulating layer 120a is formed on the lower surface of the first insulating layer 120a. As such, the second insulating layer 120b is formed using a material different from the material of the first insulating layer 120a so as to have laser processability inferior to that of the first insulating layer 120a.

Next, as shown in FIG. 8, a laser 200 is radiated, so that trenches 140 are processed in the first insulating layer 120a. As such, because the second insulating layer 120b having inferior laser processability is formed on the lower surface of the first insulating layer 120a, the second insulating layer 120b performs a stopper function, whereby the trenches 140 are processed only in the first insulating layer 120a. Accordingly, the trenches 140 having the same depth and the same width are formed.

Finally, as shown in FIG. 9, a negative pattern 300 is formed in the trenches 140, thus fabricating the trench substrate 100a. The negative pattern 300 may be formed by performing electroless plating and electroplating in the trenches 140 and on the first insulating layer 120a, thus forming a plating layer, and removing the plating layer formed on the upper surface of the first insulating layer 120a through mechanical and/or chemical polishing.

### Fabrication of Trench Substrate

### 2^{nd} Embodiment

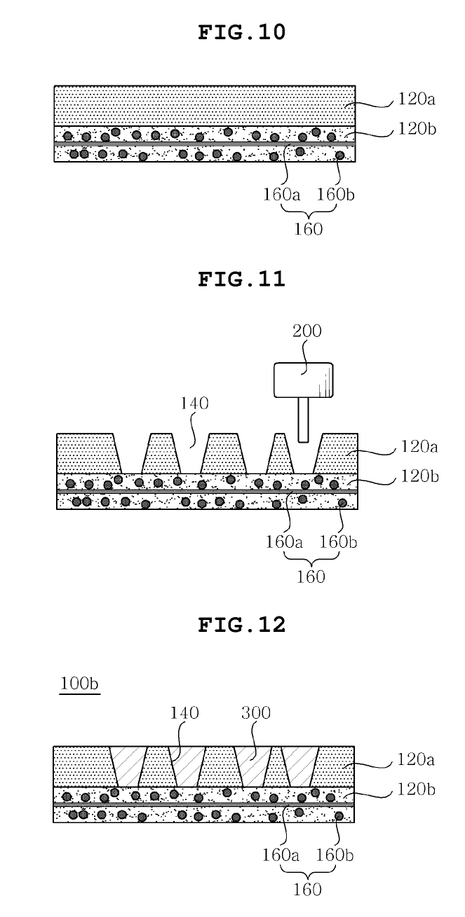

FIGS. 10 to 12 are cross-sectional views sequentially showing a process of fabricating the trench substrate according to the second embodiment of the present invention. With reference to these drawings, the method of fabricating the trench substrate 100b according to the present embodiment is described below.

As shown in FIG. 10, a first insulating layer 120a is prepared, and a second insulating layer 120b is formed on the lower surface of the first insulating layer 120a using a material which is the same as or different from the material of the first insulating layer 120a, in which the second insulating layer 120b includes a reinforcement member 160 therein so as to have laser processability inferior to that of the first insulating layer 120a.

Next, as shown in FIG. 11, a laser 200 is radiated, so that trenches 140 are processed in the first insulating layer 120a. As such, because the second insulating layer 120b including the reinforcement member 160 and thus having laser processability inferior to that of the first insulating layer 120a is formed on the lower surface of the first insulating layer 120a, the second insulating layer 120b performs a stopper function, whereby the trenches 140 are processed only in the first insulating layer 120a.

Finally, as shown in FIG. 12, a negative pattern 300 is formed in the trenches 140, thus fabricating the trench substrate 100b.

### Fabrication of Trench Substrate

### 3^{rd} Embodiment

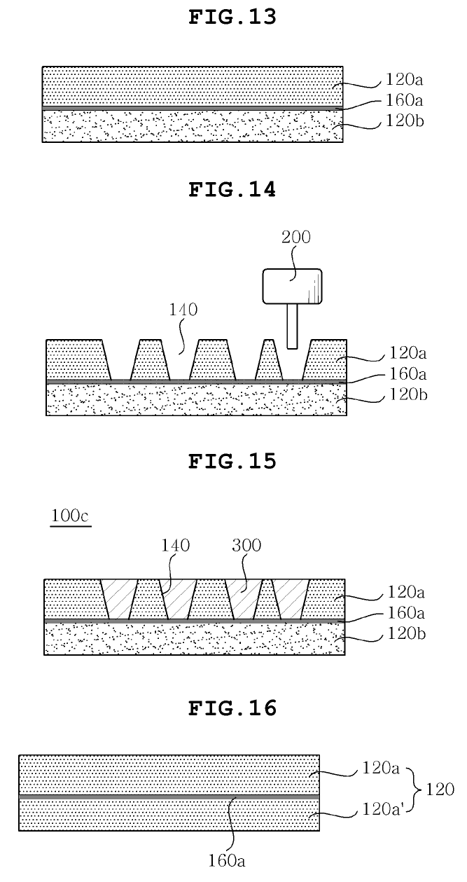

FIGS. 13 to 15 are cross-sectional views sequentially showing a process of fabricating the trench substrate according to the third embodiment of the present invention. With reference to these drawings, the method of fabricating the trench substrate 100c according to the present embodiment is described below.

As shown in FIG. 13, a first insulating layer 120a is prepared, and glass fiber 160a and a second insulating layer 120b are sequentially formed on the lower surface of the first insulating layer 120a.

Next, as shown in FIG. 14, a laser 200 is radiated, so that trenches 140 are processed in the first insulating layer 120a. As such, because the glass fiber 160a is provided on the lower surface of the first insulating layer 120a, the glass fiber 160a performs a stopper function, whereby the trenches 140 are processed only in the first insulating layer 120a.

Finally, as shown in FIG. 15, a negative pattern 300 is formed in the trenches 140, thus fabricating the trench substrate 100c.

### Fabrication of Trench Substrate

### 4^{th} Embodiment

FIGS. 16 to 18 are cross-sectional views sequentially showing a process of fabricating the trench substrate according to the fourth embodiment of the present invention. With reference to these drawings, the method of fabricating the trench substrate 100d according to the present embodiment is described below.

As shown in FIG. 16, an insulating layer 120 having glass fiber 160a therein is prepared.

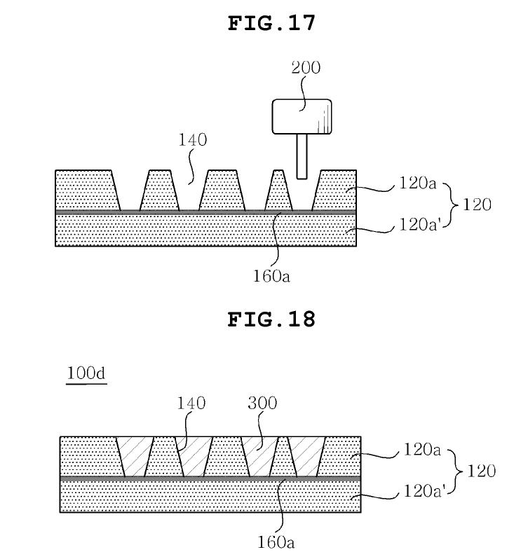

Next, as shown in FIG. 17, a laser 200 is radiated, so that trenches 140 are processed in an insulating layer 120a located at one side of the glass fiber 160a of the insulating layer 120. As such, because the glass fiber 160a performs a stopper function, the trenches 140 are processed only in the insulating layer 120a at one side of the glass fiber 160a.

Finally, as shown in FIG. 18, a negative pattern 300 is formed in the trenches 140, thus fabricating the trench substrate 100d.

As described hereinbefore, the present invention provides a trench substrate and a method of fabricating the same. According to the present invention, the trench substrate includes a first insulating layer and a second insulating layer formed on the lower surface of the first insulating layer. As such, the second insulating layer having laser processability inferior to that of the first insulating layer performs a stopper function in a laser process, so that trenches having the same shape are formed in the first insulating layer, thereby enabling the formation of a fine and uniform circuit pattern.

Also, according to the present invention, the laser processability of the second insulating layer can be lowered compared to the first insulating layer, by a simple method including forming the second insulating layer using a material different from that of the first insulating layer or incorporating glass fiber and/or a filler in the second insulating layer.

Also, according to the present invention, when glass fiber is incorporated in an insulating layer made of the same material, this glass fiber performs a stopper function in a laser process so that trenches having the same shape are formed in the first insulating layer, thereby enabling the formation of a fine and uniform circuit pattern.

Although the embodiments of the present invention regarding the trench substrate and the method of fabricating the same have been disclosed for illustrative purposes, those skilled in the art will appreciate that a variety of different modifications, additions and substitutions are possible, without departing from the scope and spirit of the invention as disclosed in the accompanying claims. Accordingly, such modifications, additions and substitutions should also be understood as falling within the scope of the present invention.

What is claimed is:

1. A trench substrate, comprising:
a first insulating layer having trenches formed therein;
a second insulating layer disposed on a lower surface of the first insulating layer and having laser processability inferior to that of the first insulating layer; and
a negative pattern formed in the trenches.

2. The trench substrate as set forth in claim 1, wherein the second insulating layer is formed of a material different from that of the first insulating layer.

3. The trench substrate as set forth in claim 1, wherein the second insulating layer is formed of a material having laser absorptivity lower than that of the first insulating layer.

4. The trench substrate as set forth in claim 3, wherein the first insulating layer is formed of a material having a dark color, and the second insulating layer is formed of a material having a bright color.

5. The trench substrate as set forth in claim 1, wherein the second insulating layer is formed of a material which is same as or different from that of the first insulating layer, and includes therein either or both of glass fiber and a filler.

6. The trench substrate as set forth in claim 5, wherein the filler comprises one or more selected from the group consisting of calcium, aluminum, magnesium, silicon, boron, and barium.

7. The trench substrate as set forth in claim 1, wherein glass fiber is formed between the first insulating layer and the second insulating layer.

8. A trench substrate, comprising:
an insulating layer including glass fiber therein and trenches formed at one side of the glass fiber; and
a negative pattern formed in the trenches.

9. The trench substrate as set forth in claim 8, wherein an insulating layer located at the other side of the glass fiber includes therein either or both of glass fiber and a filler.

10. The trench substrate as set forth in claim 9, wherein the filler comprises one or more selected from the group consisting of calcium, aluminum, magnesium, silicon, boron, and barium.

11. A method of fabricating a trench substrate, comprising:
providing a first insulating layer and forming a second insulating layer having laser processability inferior to that of the first insulating layer on a lower surface of the first insulating layer;
forming trenches in the first insulating layer using a laser; and
plating the trenches, thus forming a negative pattern.

12. The method as set forth in claim 11, wherein the second insulating layer is formed of a material different from that of the first insulating layer.

13. The method as set forth in claim 11, wherein the second insulating layer is formed of a material which is same as or different from that of the first insulating layer, and includes therein either or both of glass fiber and a filler.

14. The method as set forth in claim 13, wherein the filler comprises one or more selected from the group consisting of calcium, aluminum, magnesium, silicon, boron, and barium.

15. The method as set forth in claim 11, wherein glass fiber is formed between the first insulating layer and the second insulating layer.

16. A method of fabricating a trench substrate, comprising:
providing an insulating layer including glass fiber therein and forming trenches at one side of the glass fiber; and
plating the trenches, thus forming a negative pattern.

17. The method as set forth in claim 16, wherein an insulating layer located at the other side of the glass fiber includes therein either or both of glass fiber and a filler.

18. The method as set forth in claim 17, wherein the filler comprises one or more selected from the group consisting of calcium, aluminum, magnesium, silicon, boron, and barium.
